(19) United States
(12) Patent Application Publication
(10) Pub. No.: US 2026/0082974 A1
(43) Pub. Date: Mar. 19, 2026

(54) Semiconductor Device and Method of Making Using Epoxy-Solder Paste

(71) Applicant: JCET STATS ChipPAC Korea Limited, Incheon (KR)

(72) Inventors: Yeojun Yun, Incheon (KR); SeungHyun Lee, Incheon (KR); HeeSoo Lee, Incheon (KR)

(73) Assignee: JCET STATS ChipPAC Korea Limited, Incheon (KR)

(21) Appl. No.: 18/884,536

(22) Filed: Sep. 13, 2024

(51) Int. Cl. H01L 23/00; H01L 25/16

(52) U.S. Cl. CPC H10W 72/072; H10W 72/0711; H10W 72/20; H10W 72/01251; H10W 72/016; H10W 72/07141; H10W 72/07188; H10W 72/07207; H10W 72/07255; H10W 72/225; H10W 72/251; H10W 72/253; H10W 90/00; H10W 90/724

(57) ABSTRACT

A semiconductor device has a substrate. The substrate is disposed on a quartz carrier. An electrical component is disposed over the substrate opposite the quartz carrier. An epoxy-solder paste bump is disposed between the substrate and electrical component. The epoxy-solder paste bump comprises an epoxy and a solder powder disposed in the epoxy. Laser energy is applied to a surface of the substrate through the quartz carrier. The laser energy is converted to thermal energy to reflow the solder powder and cure the epoxy.

### FIELD OF THE INVENTION

The present invention relates in general to semiconductor devices and, more particularly, to semiconductor devices and methods of making using epoxy-solder paste.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Laser-assisted bonding (LAB) has emerged as a next-generation flip-chip bonding technology to overcome limitations in the mass-reflow process. The heating mechanism of the LAB process is based on the absorption of photon energy by silicon material, which converts to heat energy due to indirect band gap characteristics. As a result, the vibration energy of atoms rises, inducing a temperature increase. However, the fast heating process of infrared (IR) lasers induces voids in the surface mount solder bumps, among other problems with the process. Accordingly, a need exists for an improved surface mount technique.

### BRIEF DESCRIPTION OF THE DRAWINGS

FIGS. 1a-1c illustrate a semiconductor wafer with a plurality of semiconductor die separated by a saw street;

FIGS. 2a-2h illustrate forming a semiconductor package using epoxy-solder paste; and

FIGS. 3a and 3b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

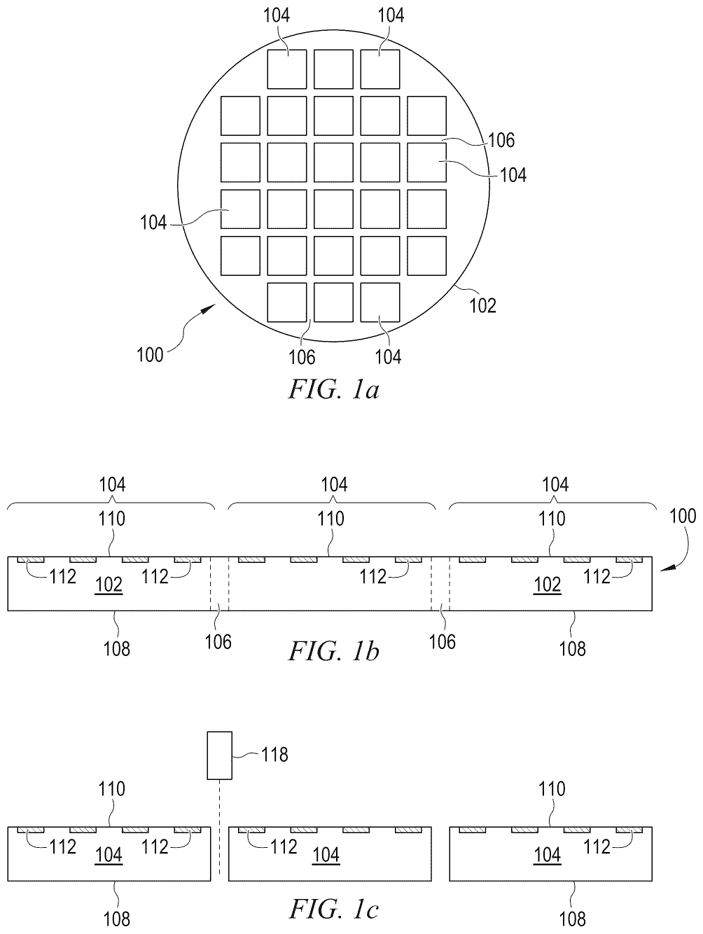

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

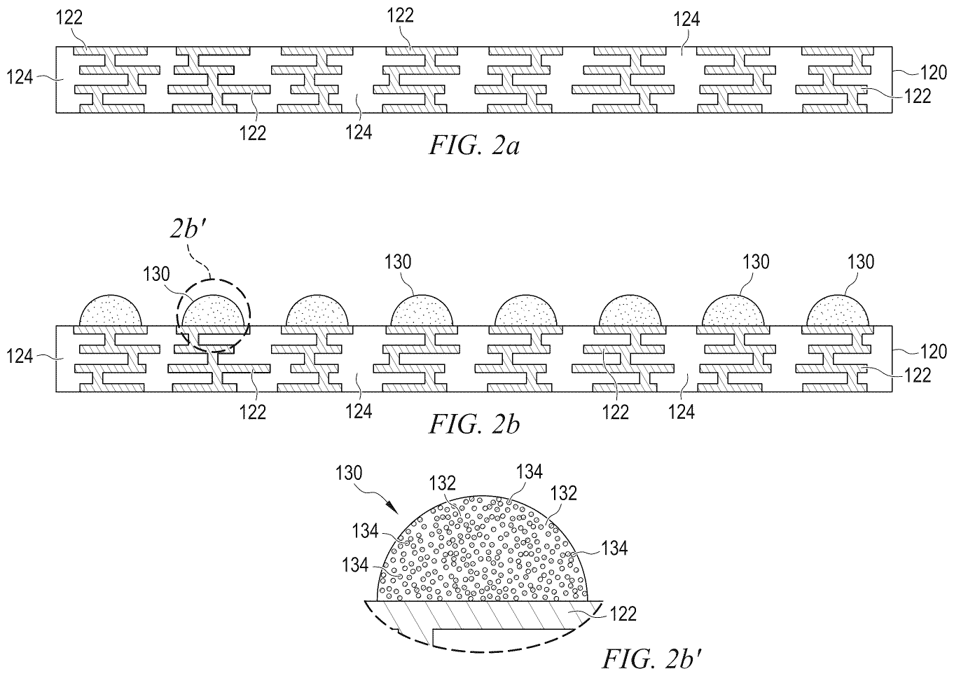

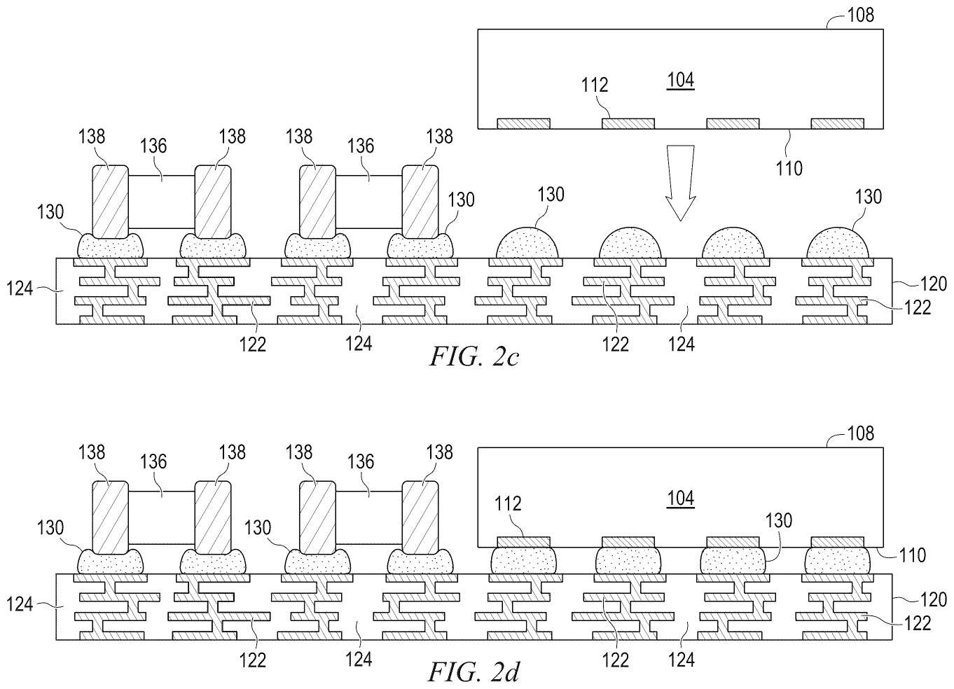

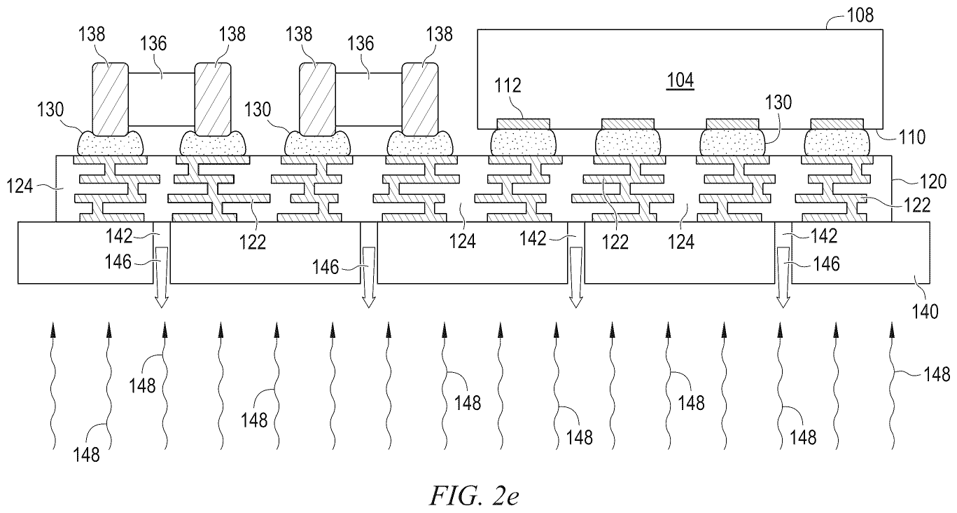

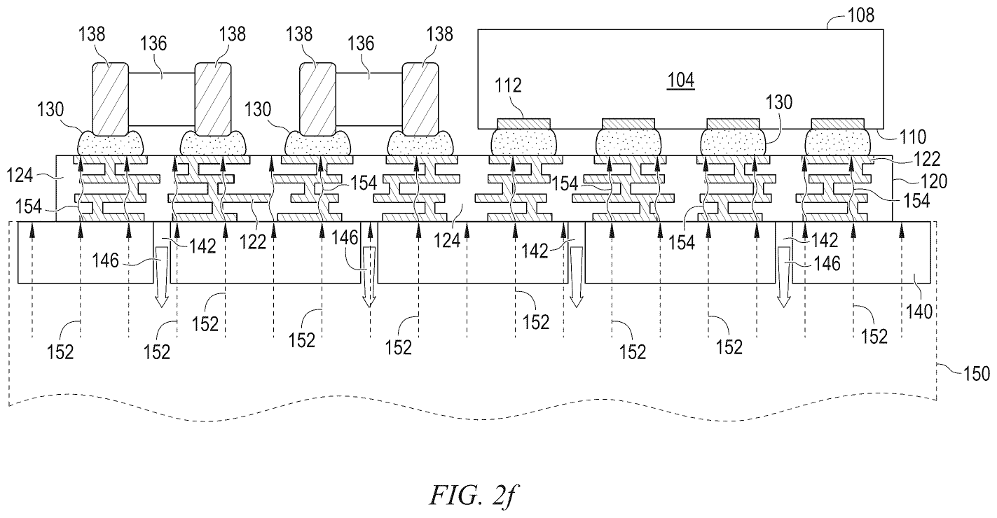

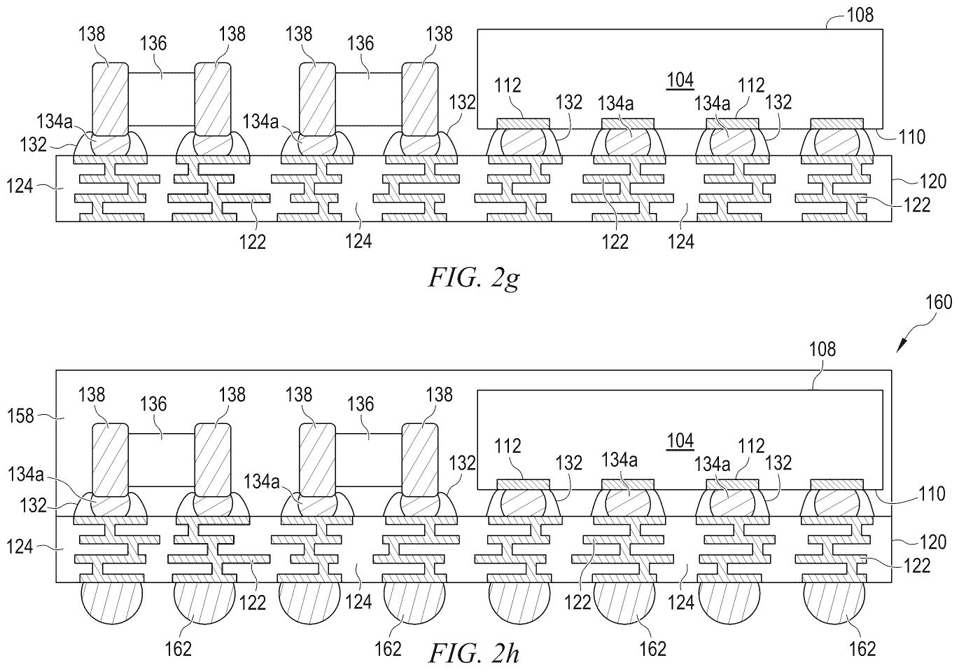

FIGS. 2a-2h illustrate a method of making a semiconductor package using an advanced laser-based surface mount solder process with epoxy-solder paste. FIG. 2a shows a package substrate 120. Substrate 120 is a multi-layered interconnect substrate including conductive layers 122 and insulating layers 124. While only a single substrate 120 suitable to form a single semiconductor package is shown, hundreds or thousands of units are commonly manufactured on, and processed as part of, a single substrate before being singulated from each other, using the same steps described herein performed en masse. A separate substrate 120 could also be used for each package being manufactured, the substrate being singulated before the steps shown hereafter and a plurality of individual substrates being placed on a common carrier for processing.

Conductive layers 122 can be one or more layers of Al, Cu, Sn, Ni, Au, Ag, or other suitable electrically conductive material. Conductive layers 122 can be formed using PVD, CVD, electrolytic plating, electroless plating, or other suitable metal deposition process. Conductive layers 122 provide horizontal electrical interconnect across substrate 120 and vertical electrical interconnect between top and bottom surfaces. Portions of conductive layers 122 can be electrically common or electrically isolated depending on the design and function of the package being formed.

Insulating layers 124 contain one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layers 124 can be formed using PVD, CVD, printing, lamination, spin coating, spray coating, sintering, thermal oxidation, or another suitable process. Insulating layers 124 provide isolation between conductive layers 122. Any number of conductive layers 122 and insulating layers 124 can be interleaved over each other to form substrate 120.

Any other suitable type of package substrate or leadframe is used for substrate 120 in other embodiments. For example, substrate 120 can be a laminate interposer, PCB, wafer-form, strip interposer, leadframe, or another suitable substrate. Substrate 120 may include one or more laminated layers of polytetrafluoroethylene pre-impregnated (prepreg), FR-4,FR-1, CEM-1, or CEM-3 with a combination of phenolic cotton paper, epoxy, resin, woven glass, matte glass, polyester, and other reinforcement fibers or fabrics. Substrate 120 can also be a multi-layer flexible laminate, ceramic, copper clad laminate, glass, or semiconductor wafer including an active surface containing one or more transistors, diodes, and other circuit elements to implement analog circuits or digital circuits.

In FIG. 2b, epoxy-solder paste bumps 130 are disposed on exposed contact pads of conductive layer 122. In some embodiments, substrate 120 is disposed on carrier 140 from FIG. 2e with thermal energy 148 being applied prior to and during formation of bumps 130. Bumps 130 are formed using screen or stencil printing, or another suitable process. FIG. 2b′ shows a detailed view of a bump 130 to better illustrate the structure of the bump. Each bump consists of an epoxy, epoxy-molding compound (EMC), or other suitable base material 132. A solder powder 134 is mixed in with epoxy 132. Solder powder 134 comprises a plurality of small pieces of solder evenly distributed throughout the volume of epoxy 132. In other embodiments, solder powder 134 comprises small pieces of Al, Sn, Ni, Au, Ag, lead (Pb), bismuth (Bi), Cu, solder, or combinations thereof. For example, the solder powder material can be eutectic Sn/Pb, Sn—Ag—Cu, high-lead solder, or lead-free solder. In some embodiments, bumps 130 also include a hardener, a reducing agent, and a catalyst in addition to the base material epoxy 132 and solder powder 134.

The epoxy-solder paste material used for bumps 130 has epoxy 132 and solder powder 134 pre-mixed prior to depositing on substrate 120. Solder powder 134 has small enough pieces that, in some embodiments, the introduction of the solder powder into epoxy 132 does not appreciably change the consistency of the epoxy, which remains as a gel. Therefore, any suitable epoxy deposition method can be used to deposit bumps 130 onto substrate 120. In other embodiments, solder powder 134 makes epoxy 132 more of a paste consistency, in which case any solder paste deposition method can be used. Bumps 130 are formed on contact pads of conductive layer 122 where surface mount or other components are to be mounted or installed, which may not be every contact pad in some embodiments.

Any desired electrical components to implement the electrical functionality of the semiconductor package being formed are mounted on substrate 120 in FIG. 2c, including semiconductor die 104 from FIG. 1c. Additional electrical components 136 are disposed on substrate 120 alongside semiconductor die 104. For example, electrical components 136 can be discrete electrical devices, such as diodes, transistors, resistors, capacitors, or inductors. Electrical components 136 can include other semiconductor die, semiconductor packages, surface mount devices, RF components, discrete electrical devices, and may include integrated passive devices (IPDs).

Semiconductor die 104 and electrical components 136 are positioned over substrate 120 using a pick and place operation. Electrical components 136 are brought into contact with bumps 130. Terminals 138 of electrical components 136 are pressed into respective bumps 130, displacing the bump material. Bumps 130 remain liquid-like or semi-solid, which allows the epoxy to hold components 136 in place sufficiently for subsequent processing. Semiconductor die 104 are picked and placed with contact pads 112 physically contacting bumps 130 as shown in FIG. 2d. Epoxy 132 remains uncured with solder powder 134 evenly distributed throughout the entire volume of bumps 130. In one embodiment, bumps 130 are formed on the components being mounted prior to mounting rather than, or in addition to, being formed on substrate 120. In other embodiments, bumps 130 are formed on substrate 120 as illustrated, and the electrical components, such as semiconductor die 104, have purely solder bumps, formed as discussed below for bumps 162, that will be reflowed together with solder powder 134 by laser 150 in FIG. 2f.

In FIG. 2e, substrate 120 is disposed on a carrier 140. In some embodiments, substrate 120 is on carrier 140 for the preceding steps, including deposition of bumps 130. Carrier 140 is a quartz block in one embodiment. Other materials that are transmissive, translucent, or transparent to infrared lasers are used in other embodiments. Carrier 140 includes optional vacuum openings 142, through which a vacuum 146 is applied to substrate 120 to keep the substrate flat on the carrier and thereby reduce warpage. Vacuum 146 applies a downward force through openings 142, which are distributed across the entire footprint of substrate 120. Vacuum 146 pulls substrate 120 down against carrier 140. Because carrier 140 is flat, the vacuum pressure helps maintain flatness of substrate 120. While openings 142 are illustrated as extending linearly completely through carrier 140, other embodiments have the openings interconnected within the carrier to a single vacuum hookup location for applying the vacuum.

Thermal energy 148 is applied to carrier 140 to maintain the carrier at between 70° C. and 100° C. In one embodiment, substrate 120 is disposed on carrier 140 at the elevated temperature during each of the previously described steps, e.g., deposition of bumps 130 onto the substrate.

Thermal energy 148 can be applied using any suitable means, e.g., by using a resistive electrical heater or other type of thermal heater disposed adjacent to or around carrier 140.

Thermal energy 148 can be applied to carrier 140 using conduction, convection, radiation, or any other suitable mechanism. Keeping substrate 120 at an elevated temperature on a preheated carrier 140 reduces thermal shock of solder from the sudden temperature rise of subsequent reflow.

In FIG. 2f, a laser beam 150 is applied to the bottom of carrier 140. The quartz material of carrier 140 efficiently transfers IR laser photons or energy 152 through the carrier such that greater than 99. 97% of laser energy is transmitted through the carrier to substrate 120. Laser energy 152 is absorbed by substrate 120 and converted into thermal energy 154 that travels through the substrate to bumps 130. Laser beam 150 is an infrared (IR) laser beam generated by an infrared laser disposed under carrier 140 and substrate 120. In some embodiments, the source of thermal energy 148 continues to apply thermal energy 148 while laser energy 152 is also applied to substrate 120 through carrier 140 at the same time.

Laser beam 150 is applied to substrate 120 for five seconds in one embodiment. In other embodiments, laser 150 is applied for a sufficient amount of time for thermal energy 154 to raise the temperature of bumps 130 to between 210° C. and 220° C. A temperature between 210° C. and 220° C. is sufficient to both reflow solder powder 134 and also cure epoxy 132. Once reflowed, the separate pieces of solder powder 134 are attracted to each other and combine into a solder bump 134a as shown in FIG. 2g. The IR laser reflow of solder powder 134 can be completed without requiring a flux, which eliminates a major cause of solder voids within solder bumps, thereby creating more reliable electrical connections. The fast temperature rise time provided by heating with laser 150, with the target temperature being reached in approximately five seconds, helps to ensure that solder powder 134 gathers into a single continuous body of solder material without openings or voids.

Reflow of solder powder 134 physically separates the solder powder from epoxy 132 in FIG. 2g. Epoxy 132 remains as a protective coating around each of the solder bumps 134a, entirely or nearly entirely free of solder powder 134, and is cured by the same thermal energy 154 that reflowed the solder powder. Epoxy 132 completely surrounds and seals solder bumps 134a. Epoxy 132 physically contacts terminals 138 and substrate 120 to completely enclose solder bumps 134a.

After laser heating in FIG. 2f, a cooling time of ten seconds is provided. During the cooling time or cooldown period, laser 150 is turned off and thermal energy 148 is optionally discontinued. If thermal energy 148 is discontinued for cooldown, the thermal energy is turned on again after cooldown to maintain carrier 140 within the range of 70-100° C. for the next LAB operation of another set of substrate 120, semiconductor die 104, and electrical components 136. The ten second cooling time is typically sufficient for solder bumps 134a to solidify so that further processing can occur in most embodiments. Approximately 10 seconds, or any other suitable amount of cooling time, can be used as necessary in other embodiments. After cooling in FIG. 2g, solder bumps 134a physically and electrically couple semiconductor die 104 and electrical components 136 to substrate 120. Epoxy 132 around solder bumps 134a protects the solder bumps and also bolsters the physical connection of semiconductor die 104 and electrical components 136 to substrate 120.

In FIG. 2h, an encapsulant or molding compound 158 is deposited over and around semiconductor die 104, electrical components 136, and substrate 120 using a paste printing, compression molding, transfer molding, liquid encapsulant molding, vacuum lamination, spin coating, or other suitable applicator. Encapsulant 158 can be liquid or granular polymer composite material, such as epoxy resin, epoxy acrylate, or another suitable polymer, with or without a filler. Encapsulant 158 is non-conductive, provides structural support, and environmentally protects the semiconductor device from external elements and contaminants.

A semiconductor package 160 is completed by adding solder bumps 162 to the bottom of substrate 120 and, if necessary, singulating the panel of substrate 120 and encapsulant 158 into individual packages. To form solder bumps 162, an electrically conductive bump material is deposited over contact pads of conductive layer 122 exposed on a surface of the substrate opposite semiconductor die 104, electrical components 136, and encapsulant 158 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 162. Bumps 162 can be formed over an under-bump metallization (UBM) having a wetting layer, barrier layer, and adhesion layer, which was previously formed on conductive layer 122. Bumps 162 can also be compression bonded or thermocompression bonded to conductive layer 122. Bump 162 represents one type of interconnect structure that can be formed over conductive layer 122. The interconnect structure can also use bond wires, conductive paste, stud bump, micro bump, or other electrical interconnect.

Semiconductor package 160 has surface mount components, e.g., semiconductor die 104 and electrical components 136, mounted to substrate 120 using a fluxless soldering process with epoxy-solder paste. The soldering process improves or eliminates many issues that stem from the flux process in the prior art, e.g., breakdown of electronics, EMC delamination, solder extrusion, solder voids, etc. Moreover, the manufacturing process is simplified by not requiring a step of cleaning flux after reflow. The IR laser heating technique combined with epoxy-solder paste bumps improves manufacturing units per hour and reliability of the solder bump bond. Epoxy 132 remains as a protective coating around solder bumps 134a, which protects the solder bumps and improves reliability. Epoxy 132 remaining as an insulating layer around solder bumps 134a also helps eliminate electrical short circuits caused by whickers, which sometimes form extending from solder bumps when using laser reflow.

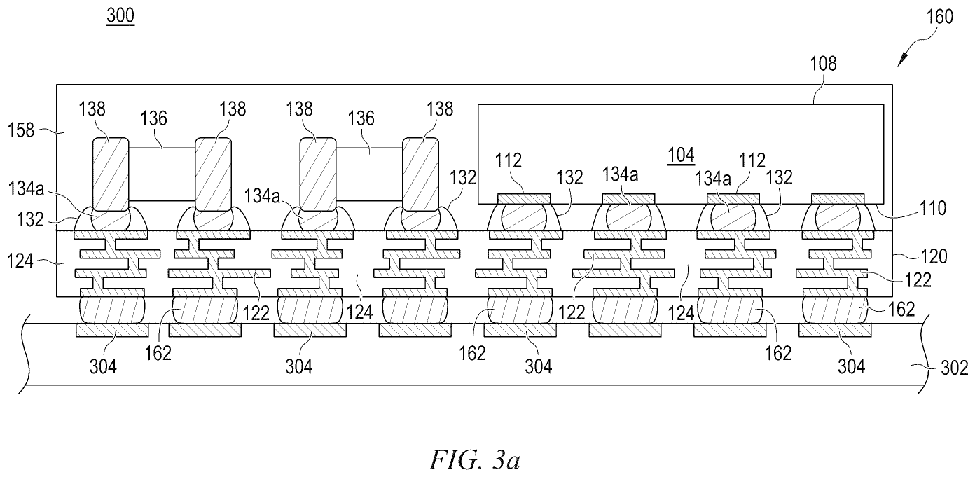

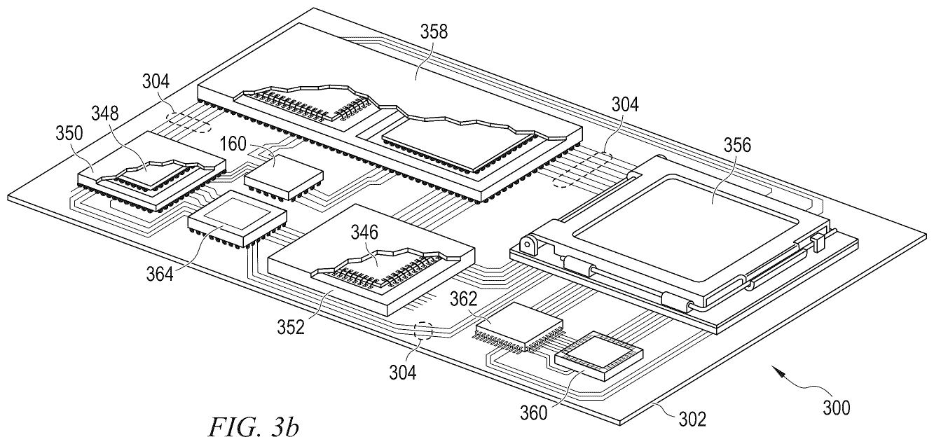

FIGS. 3a and 3b illustrate integrating the above-described semiconductor packages, e.g., semiconductor package 160, into a larger electronic device 300. FIG. 3a illustrates a partial cross-section of semiconductor package 160 mounted onto a printed circuit board (PCB) or other substrate 302 as part of electronic device 300. Solder bumps 162 are reflowed onto conductive layer 304 of PCB 302 to physically attach and electrically connect semiconductor package 160 to the PCB. In other embodiments, thermocompression or another suitable attachment and connection methods are used. In some embodiments, an adhesive or underfill layer is used between semiconductor package 160 and PCB 302. Semiconductor die 104 and electrical components 136 are electrically coupled to conductive layer 304 through substrate 120.

FIG. 3b illustrates electronic device 300 having a chip carrier substrate or PCB 302 with a plurality of semiconductor packages disposed on a surface of PCB 302, including semiconductor package 160. Electronic device 300 can have one type of semiconductor package, or multiple types of semiconductor packages, depending on the application. In other embodiments, semiconductor package 160 is incorporated as only one part of another larger semiconductor package, e.g., a system-in-package, before being incorporated into a larger electronic device 300.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 3b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate;
disposing the substrate on a quartz carrier;
disposing an electrical component over the substrate opposite the quartz carrier;
disposing an epoxy-solder paste bump between the substrate and electrical component, wherein the epoxy-solder paste bump comprises an epoxy and a solder powder disposed in the epoxy; and
applying laser energy to a surface of the substrate through the quartz carrier, wherein the laser energy is converted to thermal energy to reflow the solder powder and cure the epoxy.

2. The method of claim 1, wherein reflowing the solder powder causes the solder powder to collect and form a solder bump between the substrate and electrical component.

3. The method of claim 2, wherein the epoxy remains as a coating around the solder bump after reflow.

4. The method of claim 1, further including:
disposing the epoxy-solder paste bump on the substrate; and
disposing the electrical component on the epoxy-solder paste bump.

5. The method of claim 1, further including applying a vacuum to the substrate through an opening of the quartz carrier.

6. The method of claim 1, further including applying a thermal energy to the carrier prior to applying the laser energy.

7. A method of making a semiconductor device, comprising:
providing a substrate;
disposing an electrical component over the substrate;
disposing an epoxy-solder paste bump between the substrate and electrical component, wherein the epoxy-solder paste bump comprises an epoxy and a solder powder disposed in the epoxy; and
applying laser energy to a surface of the substrate opposite the electrical component, wherein the laser energy is converted to thermal energy to reflow the solder powder and cure the epoxy.

8. The method of claim 7, wherein reflowing the solder powder causes the solder powder to collect and form a solder bump between the substrate and electrical component.

9. The method of claim 8, wherein the epoxy remains as a coating around the solder bump after reflow.

10. The method of claim 7, further including:
disposing the epoxy-solder paste bump on the substrate; and
disposing the electrical component on the epoxy-solder paste bump.

11. The method of claim 7, further including:
disposing the substrate on a carrier; and
applying a vacuum to the substrate through an opening of the carrier while applying laser energy.

12. The method of claim 7, further including:
disposing the substrate on a carrier; and
applying a thermal energy to the carrier prior to applying the laser energy.

13. The method of claim 7, further including applying laser energy to the surface of the substrate for five seconds followed by a cooldown period of ten seconds.

14. A method of making a semiconductor device, comprising:
providing a substrate;
disposing an electrical component over the substrate;
disposing an epoxy-solder paste bump between the substrate and electrical component; and
applying laser energy to a surface of the substrate opposite the electrical component.

15. The method of claim 14, wherein applying the laser energy reflows a solder powder of the epoxy-solder paste bump to form a solder bump between the substrate and electrical component.

16. The method of claim 15, wherein an epoxy of the epoxy-solder paste bump remains as a coating around the solder bump after reflow.

17. The method of claim 14, further including:
disposing the epoxy-solder paste bump on the substrate; and
disposing the electrical component on the epoxy-solder paste bump.

18. The method of claim 14, further including:
disposing the substrate on a carrier; and
applying a vacuum to the substrate through an opening of the carrier while applying laser energy.

19. The method of claim 14, further including:
disposing the substrate on a carrier; and
applying a thermal energy to the carrier prior to applying the laser energy.

20. The method of claim 14, further including applying laser energy to the surface of the substrate for five seconds followed by a cooldown period of ten seconds.

21. A semiconductor device, comprising:
a substrate;
an electrical component disposed over the substrate; and
an epoxy-solder paste bump disposed between the substrate and electrical component.

22. The semiconductor device of claim 21, further including a quartz carrier disposed under the substrate.

23. The semiconductor device of claim 22, further including a thermal heater disposed adjacent to the quartz carrier.

24. The semiconductor device of claim 22, further including an infrared laser disposed under the quartz carrier.

25. The semiconductor device of claim 21, wherein the epoxy-solder paste bump includes a solder powder distributed throughout an epoxy bump.
